(19) United States
(12) Patent Application Publication
(10) Pub. No.: US 2007/0034929 A1
(43) Pub. Date: Feb. 15, 2007

(54) FLASH MEMORY DEVICE AND METHOD OF MANUFACTURING THE SAME

(75) Inventors: Joo Won Hwang, Seoul (KR); Jum Soo Kim, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-shi (KR)

(21) Appl. No.: 11/164,605

(22) Filed: Nov. 30, 2005

(30) Foreign Application Priority Data
Jul. 26, 2005 (KR) 2005-67709

(51) Int. Cl. H01L 29/76

(52) U.S. Cl. 257/314

(57) ABSTRACT

A flash memory device and method of manufacturing the same includes a string structure having source select lines, a number of word lines and drain select lines, a first insulating film is filled between the word lines, between the word lines and the source select lines and between the word lines and the drain select lines upon formation of a self-aligned contact. A spacer is formed using a second insulating film on sidewalls of the source select lines and the drain select lines. In this case, the first insulating film has a dielectric constant value lower than that of the second insulating film. Accordingly, a stabilized self-aligned contact can be formed, a Vt disturbance phenomenon in a program operation can be minimized, and the operation speed of the device can be improved.

### FIELD OF THE INVENTION

The present invention relates to a flash memory device and method of manufacturing the same, and more specifically, to a flash memory device and method of manufacturing the same, wherein a Vt disturbance phenomenon in a program operation can be minimized, the operation speed of the device can be improved and a stabilized self-aligned contact can be formed.

### DISCUSSION OF RELATED ART

A flash memory is one type of non-volatile memories that can maintain data even when power is off. The flash memory can be electrically programmed and erased, and does not need a refresh function of rewriting data at a predetermined cycle. This flash memory device can be largely classified into two kinds, NOR and NAND-type flashes depending on the structure and operation condition of cells. The NOR-type flash memory has a plurality of word lines connected in parallel and can program and erase a predetermined address. The NOR-type flash memory is generally used for applications requiring a high-speed operation. In contrast, the NAND-type flash memory has a structure in which a plurality of memory cell transistors is serially connected to form one string and the one string is connected to source and drain. The NAND-type flash memory is generally used for applications for storing high-integration data.

FIG. 1 is a sectional view of a flash memory device for illustrating a method of manufacturing the device in the related art.

Referring to FIG. 1, on a semiconductor substrate 10 are formed a number of source select lines SSL, and a number of word lines WL0, WL1 that are arranged between a number of drain select lines DSL (not shown) with a predetermined distance therebetween. In this case, the number of the word lines can be 16, 32 or 64 in consideration of device and density. Hereinafter, the source select lines SSL and the drain select lines are together referred to as “select line”.

Meanwhile, the word lines WL0, WL1 or the select lines SSL have a structure in which a tunnel oxide film 11, a conductive film for floating gate 12, a dielectric film 13, a conductive film for control gate 14 and a conduction layer 15 are sequentially stacked. At this time, the conductive film for floating gate 12 and the conductive film for control gate 14 of the select lines SSL are electrically connected through a predetermined process, but are not shown connected in the drawing. The process of forming them is well known in the art and detailed description thereof will be omitted.

Thereafter, a buffer film 16 is formed on the entire structure of the semiconductor substrate 10 including the word lines WL0, WL1 and the select lines SSL. Junction regions 10A, 10B are then formed by means of an ion implant process. In this case, the junction region 10B formed between the source select lines SSL becomes a common source, and the junction region (not shown) formed between the drain select lines DSL becomes a drain that will be connected to bit lines in a subsequent process.

After a nitride film 17 is deposited on the entire structure, a blanket etch process is performed. Thereby, a spacer 17A is formed on sidewalls of the source select lines SSL between the source select lines SSL and sidewalls of the drain select lines between the drain select lines. The nitride film spacer 17A is necessarily required for the purpose of etch selectivity with an interlayer insulating film in a process of etching a contact hole for a subsequent self-aligned contact. As the nitride film 17 is deposited and the spacer 17A is formed, the nitride film 17 is filled between the word lines WL0, WL1. Therefore, the junction region 10A is not exposed, but the common source 10B or the drain is partially exposed.

A sacrifice nitride film 18 for preventing damage of cells, which is incurred by etching in a subsequent contact hole formation process, and protecting the cells from ions in an ion implant process is formed on the entire structure including the nitride film 17. The sacrifice nitride film 18 can be used as a polish-stop film in a subsequent CMP (Chemical Mechanical Polishing) process.

From the process, it can be seen that the nitride film 17 necessary upon self-aligned contact is filled between the word lines WL0, WL1. Stress is applied to the word lines WL0, WL1 due to a physical characteristic of the nitride film. It is also known that the nitride film has a dielectric constant value, which is twice or three times higher than an oxide film. For this reason, a capacitance value between the word lines WL0, WL1 becomes high. Accordingly, there are problems in that the program operation speed is lowered and a threshold voltage (Vt) of neighboring cells is changed, due to a distance phenomenon in a program operation. This phenomenon is more profound as the level of integration of devices becomes high and the distance between the word lines becomes narrow.

### SUMMARY OF THE INVENTION

An advantage of the present invention is a flash memory device and method of manufacturing the same, wherein a stabilized self-aligned contact can be formed, a Vt disturbance phenomenon in a program operation can be minimized and the operation speed of the device can be improved, in such a manner that in a string structure having source select lines, a number of word lines and drain select lines, a first insulating film is filled between the word lines, between the word lines and the source select lines and between the word lines and the drain select lines upon formation of the self-aligned contact, and a spacer is formed using a second insulating film on sidewalls of the source select lines and the drain select lines, wherein the first insulating film has a dielectric constant value lower than the second insulating film.

According to an aspect of the present invention, there is provided a flash memory device, including a number of source select lines, a number of word lines and a number of drain select lines formed on a semiconductor substrate, a first insulating film formed on the semiconductor substrate between the word lines, between the word lines and the source select lines and between the word lines and the drain select lines, and a spacer formed on sidewalls of the source select lines between the source select lines and formed of a second insulating film. In this case, the first insulating film has a dielectric constant value lower than that of the second insulating film.

According to another aspect of the present invention, there is provided a method of manufacturing a flash memory device, including the steps of forming a number of source select lines, a number of word lines and a number of drain select lines on a semiconductor substrate, burying spaces between the word lines, between the word lines and the source select lines and between the word lines and the drain select lines with a first insulating film, and forming a spacer formed of a second insulating film on sidewalls of the source select lines between the source select lines. In this case, the first insulating film has a dielectric constant value lower than that of the second insulating film.

### BRIEF DESCRIPTION OF THE DRAWINGS

FIG. 1 is a sectional view of a flash memory device for illustrating a method of manufacturing the device in the related art;

FIGS. 2a to 2g are sectional views of a flash memory device for illustrating a method of manufacturing the device according to the present invention; and

FIG. 3 is a graph showing a program speed between the conventional flash memory device and the flash memory device according to the present invention.

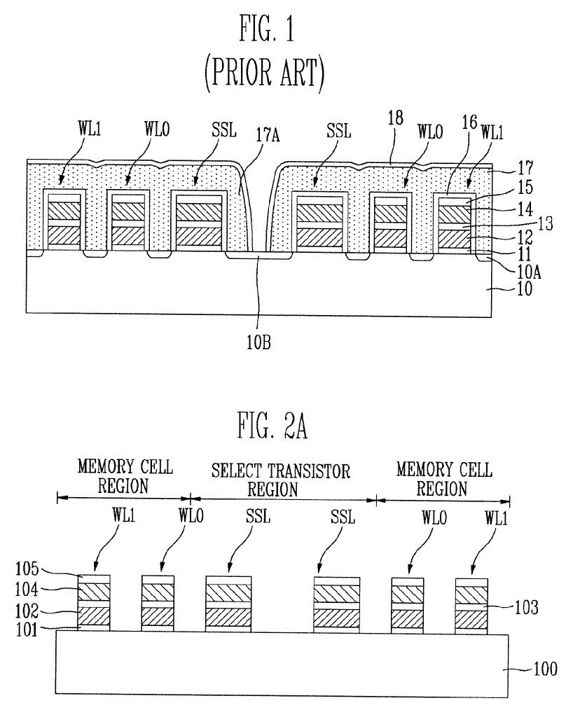

### DETAILED DESCRIPTION OF PREFERRED EMBODIMENTS

Now, the preferred embodiments according to the present invention will be described with reference to the accompanying drawings. Since preferred embodiments are provided for the purpose that the ordinary skilled in the art are able to understand the present invention, they may be modified in various manners and the scope of the present invention is not limited by the preferred embodiments described later.

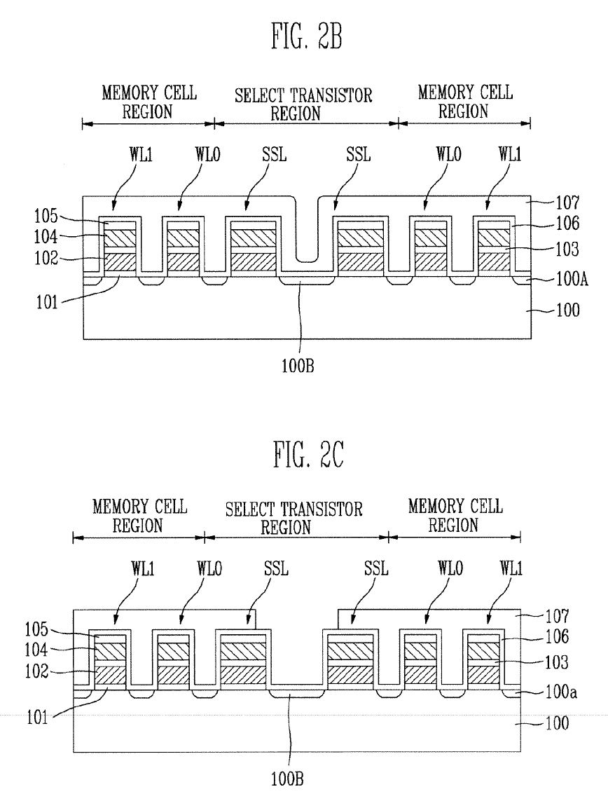

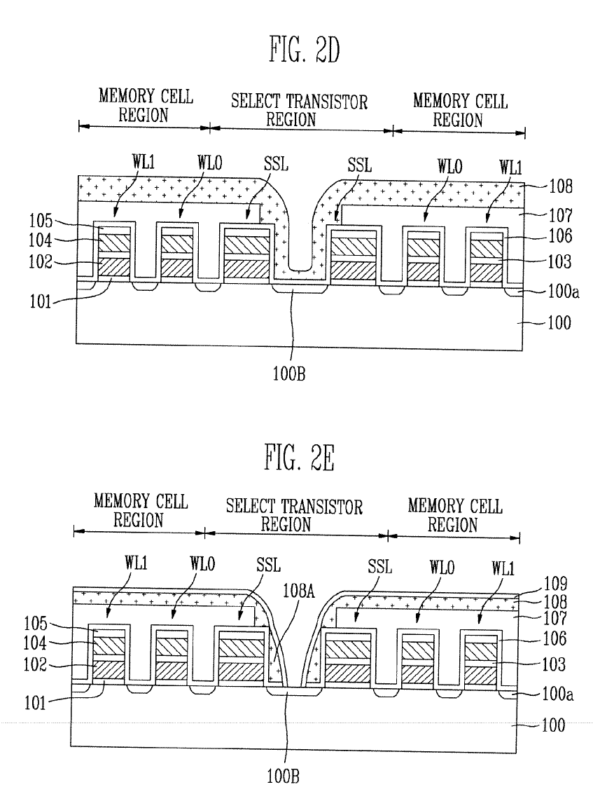

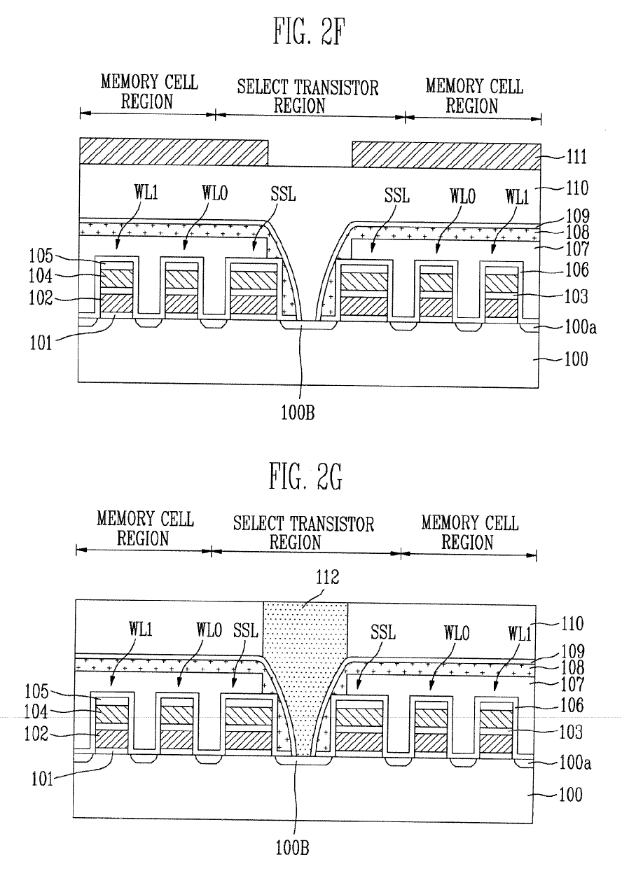

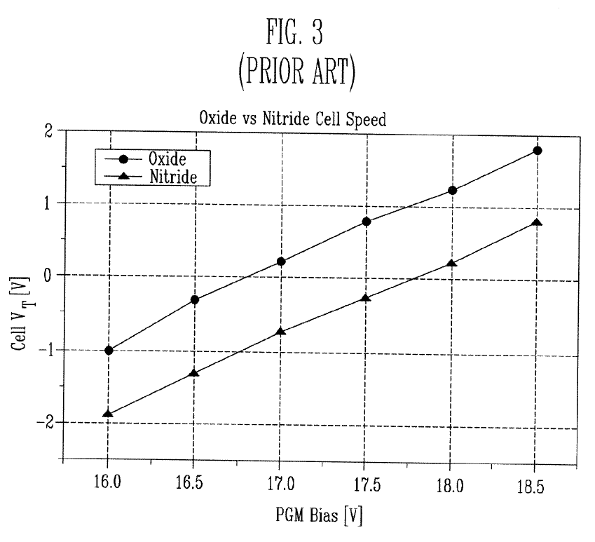

FIGS. 2a to 2g are sectional views of a flash memory device for illustrating a method of manufacturing the device according to the present invention. An embodiment of the present invention will be described in detail below with reference to FIGS. 2a to 2g.

Referring to FIG. 2a, a number of source select lines SSL, a number of word lines WL0, WL1 and a number of drain select lines (not shown) are formed in parallel with a predetermined distance therebetween on a semiconductor substrate 100 in which a memory cell region and a select transistor region (source select transistor region and drain select transistor region) are defined. Although 16, 32 or 64 word lines are generally formed between the source select lines SSL and the drain select lines, the word lines are shown as every two in the drawing. Hereinafter, the source select lines SSL and the drain select lines are together referred to as “select line”.

Meanwhile, the word lines WL0, WL1 or the select lines SSL have a structure in which a tunnel oxide film 101, a conductive film for floating gate 102, a dielectric film 103, a conductive film for control gate 104 and a conduction layer 105 are sequentially stacked. In this case, the conductive film for floating gate 102 and the conductive film for control gate 105 can be formed using polysilicon. The dielectric film 103 can have an ONO structure in which a first oxide film, a nitride film and a second oxide film are sequentially stacked. Furthermore, the conduction layer 105 can be formed using a stack film consisting of a metal silicide layer or W/WN. However, the conduction layer 105 is not an indispensable element and can be thus omitted.

Furthermore, the conductive film for floating gate 102 and the conductive film for control gate 104 of the select lines SSL are electrically connected through a predetermined process, but are not shown in the drawing. In one possible arrangement, upon formation of the word lines and the select line, the conductive film for floating gate 102 and the conductive film for control gate 104 of the select line may be electrically connected by removing the dielectric film from the select transistor region. As another method, in a subsequent process, a plug can be formed in the select line so that the conductive film for floating gate 102 and the conductive film for control gate 104 of the select line are connected.

Referring to FIG. 2b, in order to reduce etch damage generated in an etch process of forming a gate line, a re-oxidization process is performed. A buffer film 106 for preventing damage to a subsequent ion implant process is then formed. The buffer film 106 can be formed to have a stack structure of an oxide film, a nitride film or an oxynitride film. At this time, the oxide film can be formed to a thickness of 20μ to 200μ and the nitride film can be formed to a thickness of 10μ to 100μ.

An ion implant process is then performed to form an ion implant region 100A in the exposed semiconductor substrate 100. In this case, a junction region 100B formed between the source select lines SSL becomes a common source, and a junction region (not shown) formed between the drain select lines DSL becomes a drain to be connected to bit lines in a subsequent process.

Thereafter, a first insulating film 107 is formed on the entire structure of the semiconductor substrate 100 including the word lines and the select lines. The first insulating film 107 can be formed using an oxide film having a dielectric constant lower than a nitride film. A thickness of the first insulating film 107 can be greater than ½ of a distance between neighboring word lines. That is, a region between neighboring word lines can be fully filled with the first insulating film 107. As the region between the word lines is filled with the oxide film having a low dielectric constant, capacitance between the word lines is reduced. This results in an improved Vt hindrance characteristic of cells.

Referring to FIG. 2c, a photoresist is coated on the entire structure of the semiconductor substrate 100 including the first insulating film 107. Exposure and development processes are then performed to form a photoresist pattern (not shown). Thereafter, an etch process using the photoresist pattern as an etch mask is performed to remove the first insulating film 107 formed in the region between the select lines of the semiconductor substrate 100. At this time, the buffer film 106 can be removed by controlling an etch process time or performing a subsequent cleaning process using phosphoric acid. Thereby, the first insulating film 107 remains only between the word lines WL0, WL1, between the word line and the source select lines SSL, and between the word line and the drain select lines, and the junction region 100B is exposed.

Referring to FIG. 2d, a second insulating film 108 for forming a spacer is formed on the entire structure of the semiconductor substrate 100 including the first insulating film 107. In this case, the second insulating film 108 can be formed using a nitride film. At this time, since the first insulating film 107 is buried in the region between the word lines, the second insulating film 108 is not formed in the region between the word lines. Accordingly, cell stress incurred by the second insulating film 108 can be prevented and capacitance between the word lines WL0, WL1 can be prevented from increasing.

Referring to FIG. 2e, an etch process is performed to etch the second insulating film 108 so that the common source region is exposed, thus forming an insulating film the spacer 108A on sidewalls of the source select lines SSL and the drain select lines. In this case, the etch process can employ a dry etch process. A sacrifice nitride film 109 for preventing damage of cells, which is incurred by etching in a subsequent contact hole formation process, and protecting the cells from ions in an ion implant process is formed on the entire structure of the semiconductor substrate 100, including the second insulating film 108. The sacrifice nitride film 109 can be used as a polish-stop film in a subsequent CMP process.

The self-aligned contact process can be performed using the second insulating film 107. In order to secure sufficient etch margin, however, the sacrifice nitride film 109 can be formed. In this case, if etch margin is sufficient, the sacrifice nitride film 109 can be omitted.

Referring to FIG. 2f, an interlayer insulating film 110 is formed on the entire structure of the semiconductor substrate 100, including the sacrifice nitride film 109. A photoresist is then coated and exposure and phenomenon processes are performed to form a photoresist pattern 111.

Referring to FIG. 2g, the interlayer insulating film 110 is etched by an etch process using the photoresist pattern 111, thus forming a contact hole through which the ion implant region 100B of the semiconductor substrate 100 is exposed. The photoresist pattern is then stripped by means of a strip process. Thereafter, the contact hole is buried with a conductive material to form a contact plug 112.

FIG. 3 is a graph showing program speeds when the region between the word lines is filled with an oxide film (for example, in accordance with the present invention) and the region between the word lines is filled with a nitride film. From FIG. 3, it can be seen that the case where the region between the word lines is filled with the oxide film has a program speed, which is about 1V faster than the case where the region between the word lines is filled with the nitride film having a dielectric constant higher than the oxide film. This means that the case where the region between the word lines is filled with the oxide film is about 10 times faster than the case where the region between the word lines is filled with the nitride film.

As described above, in a string structure having source select lines, a number of word lines and drain select lines, a first insulating film is filled between the word lines, between the word lines and the source select lines and between the word lines and the drain select lines upon formation of a self-aligned contact. A spacer is formed using a second insulating film on sidewalls of the source select lines and the drain select lines. In this case, the first insulating film has a dielectric constant value lower than that of the second insulating film. Accordingly, a stabilized self-aligned contact can be formed, a Vt disturbance phenomenon in a program operation can be minimized, and the operation speed of the device can be improved.

Although the foregoing description has been made with reference to the preferred embodiments, it is to be understood that changes and modifications of the present invention may be made by the ordinary skilled in the art without departing from the spirit and scope of the present invention and appended claims.

What is claimed as new and desired to be protected by Letters Patent of the United States is:

1. A flash memory device, comprising:
a number of source select lines, a number of word lines and a number of drain select lines formed on a semiconductor substrate;
a first insulating film formed on the semiconductor substrate between the word lines, between the word lines and the source select lines and between the word lines and the drain select lines; and
a spacer formed on sidewalls of the source select lines between the source select lines, the spacer being formed of a second insulating film,
wherein the first insulating film has a dielectric constant value lower than a dielectric constant value of the second insulating film.

2. The flash memory device as claimed in claim 1, further comprising a spacer formed on sidewalls of the drain select lines between the drain select lines, the spacer being formed of the second insulating film.

3. The flash memory device as claimed in claim 1, wherein the word lines, the source select lines and the drain select lines consist of a tunnel oxide film, a first conduction film for a floating gate, a dielectric film and a second conduction film for control gate are sequentially stacked.

4. The flash memory device as claimed in claim 1, further comprising a buffer film formed on the semiconductor substrate including the word lines, the source select lines and the drain select lines.

5. The flash memory device as claimed in claim 1, further comprising a junction region formed in the semiconductor substrate between the word lines, a common source region formed in the semiconductor substrate between the source select lines, and a common drain region formed in the semiconductor substrate between the drain select lines.

6. The flash memory device as claimed in claim 1, wherein the insulating film has a thickness greater than ½ of a distance between the word lines.

7. The flash memory device as claimed in claim 1, further comprising a sacrifice nitride film formed on the entire surface of the semiconductor substrate including, a top of the spacer.

8. A method of manufacturing a flash memory device, comprising the steps of:
forming a number of source select lines, a number of word lines and a number of drain select lines on a semiconductor substrate;
burying spaces between the word lines, between the word lines and the source select lines and between the word lines and the drain select lines with a first insulating film; and
forming a spacer formed of a second insulating film on sidewalls of the source select lines between the source select lines,
wherein the first insulating film has a dielectric constant value lower than a dielectric constant value of the second insulating film.

9. The method as claimed in claim 8, further comprising the steps of:
forming an interlayer insulating film on the entire structure of the semiconductor substrate after the spacer is formed;
etching a predetermined region of the interlayer insulating film to form a contact hole through which the semiconductor substrate is exposed; and
burying the contact hole with a conductive material to form a contact plug.

10. The method as claimed in claim 8, wherein the word lines, the source select lines and the drain select lines are formed by sequentially stacking and selectively etching a tunnel oxide film, a first conduction film, a dielectric film and a second conduction film.

11. The method as claimed in claim 8, further comprising the step of, after the word lines, the source select lines and the drain select lines are formed, forming a buffer film on the semiconductor substrate including the word lines, the source select lines and the drain select lines before the first insulating film is formed.

12. The method as claimed in claim 11, wherein the buffer film is formed using a nitride film, an oxide film or an oxynitride film.

13. The method as claimed in claim 12, wherein the nitride film is formed to a thickness of 10μ to 100μ and the oxide film is formed to a thickness of 20μ to 200μ.

14. The method as claimed in claim 11, further comprising the step of, after the buffer film is formed, performing an ion implant process to form an ion implant region before the first insulating film is formed.

15. The method as claimed in claim 11, further comprising the step of, after the word lines, the source select lines and the drain select lines are formed, performing a re-oxidization process before the buffer film is formed.

16. The method as claimed in claim 8, wherein the oxide film has a thickness greater than ½ of a distance between adjacent word lines.

17. The method as claimed in claim 8, wherein the etch process comprises a dry etch process to remove an oxide film formed in a region between adjacent source select lines or a region between adjacent drain select lines.

18. The method as claimed in claim 8, further comprising the step of, after the spacer is formed, forming a sacrifice nitride film on the entire structure of the semiconductor substrate, including the spacer before the interlayer insulating film is formed.
